(19) United States
(12) Patent Application Publication
(10) Pub. No.: US 2005/0124142 A1
(43) Pub. Date: Jun. 9, 2005

(54) Transposed split of ion cut materials

(76) Inventor: Robert W. Bower, Anacortes, WA (US)

Correspondence Address: JOHN P. O'BANION;O'BANION & RITCHEY LLP, 400 CAPITOL MALL SUITE 1550, SACRAMENTO, CA, 95814, US

(21) Appl. No.: 10/946,583

(22) Filed: Sep. 20, 2004

Related U.S. Application Data
(63) Continuation-in-part of application No. 10/051,623, filed on Jan. 17, 2002, now Pat. No. 6,812,547.
Application No. 10/051,623 is a continuation of application No. 09/476,456, filed on Dec. 30, 1999, now Pat. No. 6,346,458.
(60) Provisional application No. 60/114,494, filed on Dec. 31, 1998.

(51) Int. Cl. H01L 21/322

(52) U.S. Cl. 438/473

(57) ABSTRACT

A method for the transposed splitting of ion cut materials. Getters are formed and selectively introduced into a solid material. In addition, atoms are introduced into the solid material at a location that is offset spatially from the locating of the getters. The atoms introduced into the solid material are then transported to the location of the getters where they will then condense in the region of the getters. As a result, then any expunged layer that is formed by ion splitting as result of the atoms being introduced into the solid material will follow the contour of the location of the getters, and will thus be transposed from the initial location of the atoms introduced into the solid material.

### CROSS-REFERENCE TO RELATED APPLICATIONS

This application is a continuation in part of U.S. application Ser. No. 10/051,623 filed on Jan. 17, 2002, now U.S. Pat. No. ______, incorporated herein by reference in its entirety, which is a continuation of U.S. application Ser. No. 09/476,456 filed on Dec. 30, 1999, now U.S. Pat. No. 6,346,458, incorporated herein by reference in its entirety, which claims priority to U.S. provisional application Ser. No. 60/114,494, filed on Dec. 31, 1998, incorporated herein by reference in its entirety. Priority is claimed to each of the foregoing applications and patents.

### INCORPORATION BY REFERENCE

The following publications, some of which are identified herein using the reference numbers set forth below in square brackets (e.g., [1]), are incorporated herein by reference:

1. G. F. Cerofolini, R. Balboni, D. Bisero, F. Corni, S. Frabboni, G. Ottaviani, R. Tonini, R. S. Brusa, A. Zecca, M. Ceschini, G. Giebel, and L. Pavesi, Hydrogen Precipitation in Highly Oversaturated Single-Crystalline Silicon, Phys. Stat. Sol. (a) 150, 539 (1995).

2. M. Bruel, Silicon on Insulator Material Technology, Electron. Left. 31, 1201 (1995).

3. M. Bruel, Process for the Production of Thin Semiconductor Material Films, U.S. Pat. No. 5,374,564 (filed Sep. 15, 1992, issued Dec. 20, 1994).

4. X. Lu, S. S. K. Iyer, J. Min. Z. Fan, J. B. Liu, P. K. Chu, C. Hu, and N. W. Chueng, Proc. 1966 IEEE Int. SOI Conf. 96CH35937, 48 (1966).

5. Tohru Hara, Takayuki Onda, Yasuo Kakizaki, Sotaro Oshima, Taira Kltamura, Kenji Kajiyama, Tomoaki Yoneda, Kohei Sekine and Morio Inoue, Delaminations of Thin Layers by High Dose Hydrogen Ion Implantation in Silicon, J. Electrochem. Soc. Vol. 143, No. 8, August 1996L166-L168.

6. L. B. Freund, A lower bound on implant density to induce wafer splitting in forming compliant substrate structures, Appl. Phys. Lett. 70 (26), 30 Jun. 1997.

7. Q. -Y. Tong, K. Gutjahr, S. Hopfe, and U. Goesele and T. -H. Lee, Layer splitting process in hydrogen-implanted Si, Ge, SiC, and diamond substrates, Appl. Phys. Lett. 70, (11), 17 Mar. 1997 pp 1390-1392.

8. Robert W. Bower, Yang A. Li and Yong Jian Chin, The Hydrogen Ion Cut Technology Combined With Low Temperature Direct Bonding, Proceedings of SPIE, Vol. 3184, pp 24, June 1997.

9. Y. Albert Li and Robert W. Bower, Surface Conditions and Morphology of Hydrogen Ion Cut Low Temperature Bonded Thin Film Layers, Submitted JJAP.

10. Q. -Y. Tong, T. -H. Lee, L. -J. Huang, Y. -L. Chao and U. Goesele, Low Temperature Si Layer Splitting, Proceedings 1977 IEEE International SOI Conference, October 1997 pp 126-127.

11. Aditya Agarwal, T. E. Haynes, V. C. Venezia, D. J. Eaglesham, M. K. Weldon, Y. J. Chabal, and O. W. Holland, Efficient Production of Silicon-on-Insulator Films by Co-implantation of He⁺ with H⁺, Proceedings 1977 IEEE International SOI Conference, October 1997 pp 44-45.

12. J. L. Zeigler and J. P. Biersack, The Stopping and Range of Ions in Solids, Trim 95, Pergamon Press (1985) ISBN-0-08-021603-X.

13. A. D. Marwick, G. S. Oehrlein, and M. Wittmer, High hydrogen concentrations produced by segregation into p⁺ layers in silicon, Appl. Phys. Lett. 59 (2), 8 Jul. 1991, pp 198-200.

14. Robert W. Bower, Louis LeBoeuf and Y. Albert Li, “Transposed Splitting of Silicon Implanted with Spatially Offset Distributions of Hydrogen and Boron”. II Nuovo Cimento, Vol. 19 D, N. 12, pp 1871-1873, 1 Jan. 1998.

### BACKGROUND OF THE INVENTION

1. Field of the Invention

This invention pertains generally to introducing atoms into solid materials, and more particularly to forming and selectively introducing getters into a solid material and introducing atoms into the solid material wherein the location of the major concentration of the getters is offset spatially from the introduced atoms in the solid material.

2. Description of the Background Art

In recent years, it has been observed that atoms introduced into solid materials can result in a thin layer of the material being expunged from the solid material when a stiffener is attached to the solid material and a suitable stress is created to cause the layer crack and break off [1,2,3]. It has been found that the thickness of the expunged layer is very near that of the mean penetration depth of the introduced ions or the nearby damage peak created by the introduced ions, when the introduced ions are ion implanted into the solid material. It has also been observed that atoms that act as getters in semiconductor materials tend to attract and condense injected ions near the location of the getters in the material.

There has also been considerable interest in high dose hydrogen ion implantation into silicon. A recent review article describes a wealth of basic physical theory and experiments related to hydrogen implanted silicon [1]. Bruel first described the Smart Cut® technique that leads to silicon-on-insulator, SOI, material for use in silicon microcircuits [2,3]. Since that time a number of authors have described and have proposed theories to quantify the hydrogen bubble generation and crack phenomena that in combination with direct bonding leads to SOI formation [4,5,6]. Recent publications have described variations on Bruel's work. Tong et al. have described layer splitting with ion implanted hydrogen in Ge, SiC, GaAs and diamond [7].

Bower et al. have demonstrated that low temperature bonding may be used with hydrogen ion implantation to produce SOI with a bonding temperature of 200° C. and a split temperature of 400° C. [8,9]. Tong et al. have shown that boron and hydrogen when implanted to the same projected range allow optically observable surface blisters to be produced with heat treatments of 200° C. for approximately 100 minutes [10]. Agarwal et al. have demonstrated that the hydrogen ion dose may be reduced from 5×10¹⁶/cm² to 1×10¹⁶/cm² when silicon is also implanted with Helium also at a dose of 1×10¹⁶/cm² [11].

### BRIEF SUMMARY OF THE INVENTION

The present invention generally comprises the steps of forming and selectively introducing getters into a single crystalline semiconductor material and then introducing atoms into the material wherein the location of the major concentration of the getters is offset spatially from the introduced atoms in the material. When these steps are carried out so that the atoms introduced into the material can be transported in the material, then the introduced atoms may be diffused or drifted to the location of the getters that have been selectively placed in the material. The introduced atoms will then condense in the region of the getters. As a result, then any expunged layer that forms as a result of the atoms being introduced into the solid material will follow the contour of the location of the getters, and will thus be transposed from the initial location of the atoms introduced into the solid material. Therefore, this invention allows an expunged layer to be formed and transferred to a stiffener that is embedded in the material independent of the location of the introduced atoms.

In one embodiment, a method for transposed splitting of ion cut materials according to the invention comprises introducing a defect creating substance into a single crystalline semiconductor material wherein said substance functions as getters during subsequent processing of said semiconductor material; introducing a plurality of atoms into said material at a location spaced apart from the location of said getters; transporting said atoms toward said getters; and expunging a layer of said material, wherein said expunged layer has a surface with a contour defined by said getters.

In another embodiment, a method for transposed splitting of ion cut materials according to the invention comprises introducing a defect creating substance into a single crystalline semiconductor material wherein the substance functions as getters during subsequent processing of said semiconductor material; wherein said getters form a contour line in said material; introducing a plurality of atoms into said material at a location spaced apart from the location of said getters; transporting said atoms toward the location of said getters; and expunging a layer of said material, wherein said expunged layer has a surface with a contour following the contour line of said getters.

In another embodiment, a method for transposed splitting of ion cut materials according to the invention comprises introducing a defect creating substance into a single crystalline semiconductor material wherein said substance functions as getters during subsequent processing of said semiconductor material and wherein and forming a contour line in said material defined by said getters; introducing a plurality of atoms into said material at a location spaced apart from the contour line of said getters; transporting said atoms toward the contour line formed by said getters; and expunging a layer of said material along a contour line following the contour line of said getters.

In the foregoing embodiments, one mode of use is to attach the expunged layer to a second material. Another mode of use is to attach the semiconductor material to a second material prior to said expunging step.

In one embodiment, the invention comprises a layer of material for use in connection with microcircuits or nanocircuits, said layer being expunged from a single crystalline semiconductor base material, wherein said layer has a surface with a non-planar contour defined by the relative positions of a plurality of getters in the base material from which said layer is formed, wherein said layer is thereby adapted for use in connection with microcircuits or nanocircuits, and wherein said getters are formed in said base material by introducing a defect creating substance. In one mode, the layer is formed by the method comprising introducing a plurality of atoms into said base material at a location spaced apart from the location of said getters; transporting said atoms toward said getters; and expunging said layer from said base material in the region of said getters, whereby said expunged layer has said surface with a contour defined by said relative positions of said getters.

In another embodiment, the invention comprises a layer of material for use in connection with microcircuits or nanocircuits, said layer being expunged from a solid single crystalline semiconductor base material, wherein said layer has a surface with a non-planar contour defined by the relative positions of a plurality of getters in said base material from which said layer is formed, wherein said layer is thereby adapted for use in connection with microcircuits or nanocircuits, and wherein said layer is formed by the method comprising introducing a defect creating substance into said base material wherein said substance functions as getters during subsequent processing of said base material; introducing a plurality of atoms into said base material at a location spaced apart from the location of said getters; transporting said atoms toward said getters; and expunging said layer from said base material in the region of said getters, whereby said expunged layer has said surface with a contour defined by said relative positions of said getters.

In another embodiment, the invention comprises a layer of material for use in connection with microcircuits or nanocircuits, said layer being expunged from a single crystalline semiconductor material, wherein said layer has a surface with a non-planar contour defined by the relative positions of a plurality of getters in said base material from which said layer is formed, wherein said layer is thereby adapted for use in connection with microcircuits, and wherein said layer is formed by the method comprising introducing a defect creating substance into said base material wherein said substance functions as getters during subsequent processing of said base material; introducing a plurality of atoms into said semiconductor material at a location spaced apart from the location of said getters; transporting said atoms toward said getters; and expunging said layer from said base material in the region of said acceptor centers, whereby said expunged layer has said surface with a contour defined by said getters.

In a still further embodiment, the invention comprises a layer of material for use in connection with microcircuits or nanocircuits, said layer being expunged from a single crystalline semiconductor base material, wherein said layer has a surface with a non-planar contour defined by the relative positions of a plurality of getters in said base material from which said layer is formed, wherein said layer is thereby adapted for use in connection with microcircuits or nanocircuits, and wherein said layer is formed by the method comprising introducing a defect creating substance into said base material wherein said substance functions as getters during subsequent processing of said base material; introducing a plurality of atoms into said silicon material at a location spaced apart from the location of said getters; transporting said atoms toward said getters; and expunging said layer from said base material in the region of said getters, whereby said expunged layer has said surface with a contour defined by said getters.

In another embodiment, the invention comprises a single crystalline semiconductor base material for use in connection with fabrication of microcircuits or nanocircuits, wherein said base material includes a non-planar contour line along which a layer can be expunged, said contour line defined by the relative positions of a plurality of getters in said base material, wherein said getters are formed by introducing a defect creating substance into said base material. In one mode, the base material is processed according to the steps comprising introducing a plurality of atoms into said material at a location spaced apart from the location of said getters; and transporting said atoms toward said getters.

In all of the foregoing embodiments, the defect creating substance that is introduced into the single crystalline semiconductor material is selected from the group consisting essentially of B, Ga, He, Ne, Ar, Kr, Xe, C, N, Be, and Group III materials.

An object of the invention is to expunge a layer of a solid material along a contour line defined by acceptor centers formed in the material.

Another object of the invention is to transpose the initial location of atoms introduced into the solid material to the location of the acceptor centers prior to expunging a layer of the solid material using the atoms.

Another object of the invention is to ion cut a material in a region spaced apart from the location where atoms are injected into the material.

Further objects and advantages of the invention will be brought out in the following portions of the specification, wherein the detailed description is for the purpose of fully disclosing preferred embodiments of the invention without placing limitations thereon.

### BRIEF DESCRIPTION OF THE DRAWINGS

The invention will be more fully understood by reference to the following drawings which are for illustrative purposes only:

FIG. 1 schematically shows the steps of a method for forming and introducing getters in a solid material and injecting atoms into the material at a location spaced apart from the getters according to the invention.

FIG. 2 schematically shows the steps of transporting the injected atoms to the location of getters shown in FIG. 1.

FIG. 3 schematically shows the steps of splitting the material shown along a contour line following the contour line of the getters in FIG. 2 and attaching the expunged layer to a second material.

### DETAILED DESCRIPTION OF THE INVENTION

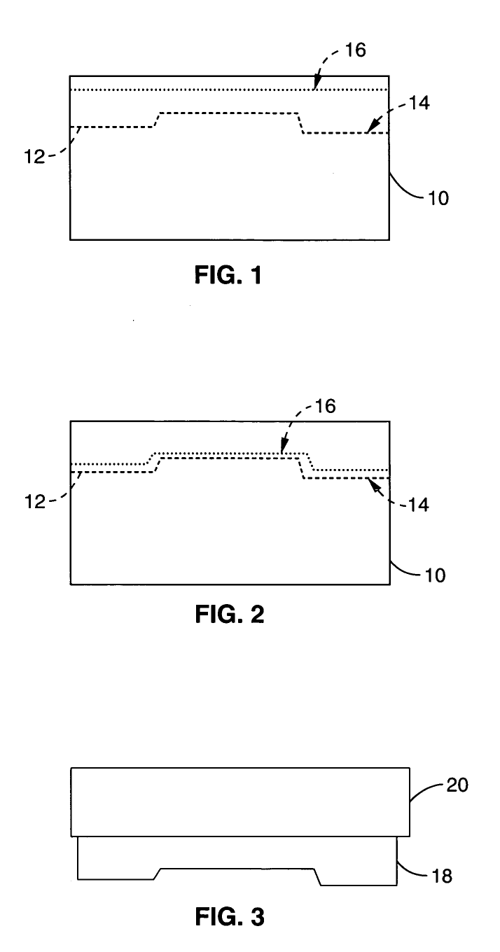

Referring more specifically to the drawings, for illustrative purposes the present invention is embodied in the process and resulting structure generally shown in FIG. 1 through FIG. 3. It will be appreciated that the structure may vary as to configuration and as to details of the elements, and that the method may vary as to the specific steps and sequence, without departing from the basic concepts as disclosed herein.

Referring first to FIG. 1, in accordance with the present invention, a defect creating substance such as Boron is used to form and selectively introduce getters into a single crystalline semiconductor material 10, such as silicon, using conventional techniques. In order to activate the getter sites and reduce any damage associated with their introduction, a high temperature rapid thermal anneal of over approximately 900° C. for a short period of time such as less than approximately 1 minute. The introduction of the defect creating substance 12 defines a “getter surface” 14 in the substrate material. Next, an ion implantation step is carried out. Atoms 16, such as Hydrogen atoms, are introduced into the substrate material, also using conventional techniques, such that the location of the major concentration of the getters is offset spatially by the range-energy considerations of the atoms introduced into the substrate. However, the ion implantation is carried out at a temperature high enough to prevent damage that would restrict the mobility of the Hydrogen atoms in the substrate material. A temperature greater than approximately 300° C. has been found to be sufficient in this regard.

Referring now to FIG. 2, after the foregoing steps are carried out, the atoms introduced into the substrate material can be transported through the material. Accordingly, the introduced atoms 16 may then be diffused or drifted to the location of the getters 12 that have been selectively placed in the material. Diffusion may occur automatically simply as a result of the conditions of the ion implantation. Or, the atoms can be drifted as a result of either internal or externally applied electric or other force fields.

The introduced atoms will then condense in the region of the getters. The material can then be split, thereby creating expunged layers. As a result of the previous steps, any expunged layer that is formed as a result of the atoms being introduced into the solid material will follow the contour of the location of the getters, namely getter surface 14, and will thus be transposed from the initial location of the atoms introduced into the solid material to the location of the getters.

Still another method of introducing and transporting the atoms to the getters would be to place the substrate material in an environment where Hydrogen would be adsorbed into the material and then diffused or drifted to the location of the activated getters.

Referring now to FIG. 3, the material is now ready for an expunged layer 18 to be formed. This expunging step is preferably carried out after the substrate material has been attached to a second substrate material 20 by bonding or gluing them together. It will be appreciated, however, that the expunged layer 18 could also be formed without bonding or gluing to a second material prior to expungement.

Note that, while the preferred embodiment of the method is to introduce the defect creating substance prior to introduction of the atoms, the substance could be introduced after introduction of the atoms as well.

### EXAMPLE 1

Boron was implanted into (100) single crystal silicon at an energy of 100 KeV, at a temperature above 300° C. with a dose of 15/cm². Trim 95 predicts a mean penetration Rp ≈306 nm and vertical straggling ΔRp ≈66.7 nm for this implanted boron [12]. The sample was then rapid thermal annealed at 95° C. for 15 seconds. The sample was then implanted with H⁺ at 40 KeV with a dose of 5×10¹⁶/cm². In this case, Trim 95 predicts a mean penetration Rp ≈457 nm and vertical straggling ΔRp≈87.3 nm for this implanted hydrogen [12]. The samples were then subjected to isochronal anneals for ten minutes at 100° C., 200° C., 300° C. and 350° C. Blistering occurred in the samples heated to 300° C. and 350° C. A small sliver split off the surface of the sample heated to 300° C. that allowed a measurement of the thickness of the expunged surface layer. The thickness of this expunged surface layer is found by this measurement to be 330±15 nm. This clearly indicates that the crack occurs within experimental error near the projected range, Rp, of the implanted boron acceptor centers, and far from the Rp of the considerably deeper hydrogen implantation of the introduced atoms into the solid material.

### EXAMPLE 2

The experimental evidence strongly suggests that the high dose implanted hydrogen into silicon migrates and accumulates in the region of the lower dose boron distribution where it blisters and cracks the silicon near the peak of the boron profile. The blister and crack time and temperature is consistent the results found by Tong et al in their experiments with boron and hydrogen implanted to the same peak depth [10]. While the migration of the hydrogen to the boron peak is reminiscent of the work of Marwick where Ga in silicon is found to attract hydrogen implanted into silicon [13]. The Marwick paper suggests that ionized Ga⁻ in silicon attracts H⁺ ions and at temperatures of ˜200° C. may attract quantities of H much in excess of the density of Ga present by the reaction:
(HGa)⁰e⁻+n H⁰→Ga⁻+(n+1)H⁰ (1)

### EXAMPLE 3

Ionized boron may attract and accumulate hydrogen in much the same manner in our work. Equation (1) does not explain where the accumulated hydrogen would reside, but other literature suggests that it might cluster near the Ga or B or perhaps in silicon defect structures that would be present after an implantation near these acceptor sites [1,13]. The importance of the RTA of the boron in our experiments is not known, but may be important in the light of the ionized donor argument just described, since without the RTA the boron would not be expected to be electrically active and act as an ionized acceptor.

Accordingly, it will be seen that this invention provides for the transposition of an ion cut layer in a substrate material by using a getter to form a surface within a substrate material toward which injected atoms can be migrated prior to splitting the material. It will be understood by those skilled in the art that this migration does not occur automatically, and that energy must be introduced in order to cause the migration. Additional energy is required to cause the material to expunge along the surface defined by the injected atoms in the vicinity of the getter material. Since the technology for forming the expunged layers, applying energy to the materials, avoiding damage of introduced atoms, introducing and forming getters, and introducing atoms are all contained in the current literature and can be practiced by one of ordinary skill in the applied materials area, such technology will not be described in detail herein.

It will be appreciated that the foregoing method described herein can have many applications and employ various materials and methods. By way of example, and not of limitation, the atoms injected can be hydrogen atoms, the substrate can be a semiconductor such as silicon, the defect creating substance used in combination with a silicon substrate can be a Group III material such as gallium or boron, the second substrate can be a semiconductor to which a silicon expunged layer could be bonded or a flexible membrane to which the expunged layer is glued, and the energy applied can be mechanical energy or heat.

As can be seen, therefore, atoms that act as getters in semiconductor materials tend to attract and condense injected ions near the location of the getters in the material. While Boron has been shown in experimental results to be a defect creating substance that can be used to form getters in silicon for collecting hydrogen atoms, other getter/ion combinations known in the art can be used as well. It should be understood that the particular defect creating substance used can depend on the species of the material into which substance is introduced. Furthermore, the defect creating substance can be selected from the group consisting essentially of B, Ga, He, C, N, Be and Group III materials to the extent that they are stable at the activation temperatures employed. It should also be recognized from the that the defect creating substance may not function as a “getter” until it has been activated through time and temperature which, can be applied as a distinct processing step or simply during subsequent processing of the material into a nanostructure or nanocircuit.

In the present invention, a first type of atom is introduced into a single crystalline semiconductor material for the purpose of forming getters in the material. This first type of atom, referred to as a defect creating substance or “getter”, is one to which a second type of atom is attracted. The second atomic species is drawn to the getters and results in the formation of a weakened region having a contour that follows the getter locations. As described herein, one example of these pairs are an activated Boron acceptor to which Hydrogen is diffused to form a weakened cutting plane.

Therefore, the invention can also be described as a method of ion split cutting which involves introducing atoms into solid materials at a first location, and then diffusing the atoms to getters which were formed by introducing a defect creating substance into a region of the material, such as those forming a cutting plane across the solid material. The resulting weakening at the cutting plane allows the solid material to be split, thereby providing a means for expunging a layer from a material, such as for removing a device layer. The resultant cut layer of material has a surface with a non-planar contour defined by the relative positions of a plurality of getters.

It should also be noted that getters are implanted into the material according to the present invention at lower concentrations (less damaging) than the atoms being implanted to form a cutting plane. The material of the present invention having getters not subject to splitting and bubbling before the getters are activated and second atomic species is introduced and diffused to the activated getter.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

1. A method for transposed splitting of ion cut materials, comprising:
(a) introducing a defect creating substance into a single crystalline semiconductor material wherein said substance functions as getters during subsequent processing of said semiconductor material;
(b) introducing a plurality of atoms into said material at a location spaced apart from the location of said getters;
(c) transporting said atoms toward said getters; and
(d) expunging a layer of said material, wherein said expunged layer has a surface with a contour defined by said getters.

2. A method as recited in claim 1, wherein said defect creating substance is selected from the group consisting essentially of B, Ga, He, Ne, Ar, Kr, Xe, C, N, Be, and Group III materials.

3. A method as recited in claim 1, further comprising attaching said expunged layer to a second material.

4. A method as recited in claim 1, wherein said semiconductor material is attached to a second material prior to said expunging step.

5. A method for transposed splitting of ion cut materials, comprising:
(a) introducing a defect creating substance into a single crystalline semiconductor material wherein the substance functions as getters during subsequent processing of said semiconductor material;
(b) wherein said getters form a contour line in said material;
(c) introducing a plurality of atoms into said material at a location spaced apart from the location of said getters;
(d) transporting said atoms toward the location of said getters; and
(e) expunging a layer of said material, wherein said expunged layer has a surface with a contour following the contour line of said getters.

6. A method as recited in claim 5, wherein said defect creating substance is selected from the group consisting essentially of B, Ga, He, Ne, Ar, Kr, Xe, C, N, Be, and Group III materials.

7. A method as recited in claim 5, further comprising the step of attaching said expunged layer to a second material.

8. A method as recited in claim 5, wherein said semiconductor material is attached to a second material prior to said expunging step.

9. A method for transposed splitting of ion cut materials, comprising:
(a) introducing a defect creating substance into a single crystalline semiconductor material wherein said substance functions as getters during subsequent processing of said semiconductor material and wherein and forming a contour line in said material defined by said getters;
(b) introducing a plurality of atoms into said material at a location spaced apart from the contour line of said getters;
(c) transporting said atoms toward the contour line formed by said getters; and
(d) expunging a layer of said material along a contour line following the contour line of said getters.

10. A method as recited in claim 9, wherein said defect creating substance is selected from the group consisting essentially of B, Ga, He, Ne, Ar, Kr, Xe, C, N, Be, and Group III materials.

11. A method as recited in claim 9, further comprising attaching said expunged layer to a second material.

12. A method as recited in claim 9, wherein said semiconductor material is attached to a second material prior to said expunging step.

13. A layer of material for use in connection with microcircuits or nanocircuits, said layer being expunged from a single crystalline semiconductor base material, wherein said layer has a surface with a non-planar contour defined by the relative positions of a plurality of getters in the base material from which said layer is formed, wherein said layer is thereby adapted for use in connection with microcircuits or nanocircuits, and wherein said getters are formed in said base material by introducing a defect creating substance.

14. A layer of material as recited in claim 13, wherein said defect creating substance is selected from the group consisting essentially of B, Ga, He, Ne, Ar, Kr, Xe, C, N, Be, and Group III materials that functions as getters during subsequent processing of said base material.

15. A layer of material as recited in claim 13, wherein said layer is formed by the method comprising:
(a) introducing a plurality of atoms into said base material at a location spaced apart from the location of said getters;
(b) transporting said atoms toward said getters; and
(c) expunging said layer from said base material in the region of said getters, whereby said expunged layer has said surface with a contour defined by said relative positions of said getters.

16. A layer of material for use in connection with microcircuits or nanocircuits, said layer being expunged from a solid single crystalline semiconductor base material, wherein said layer has a surface with a non-planar contour defined by the relative positions of a plurality of getters in said base material from which said layer is formed, wherein said layer is thereby adapted for use in connection with microcircuits or nanocircuits, and wherein said layer is formed by the method comprising:
(a) introducing a defect creating substance into said base material wherein said substance functions as getters during subsequent processing of said base material;
(b) introducing a plurality of atoms into said base material at a location spaced apart from the location of said getters;
(c) transporting said atoms toward said getters; and
(d) expunging said layer from said base material in the region of said getters, whereby said expunged layer has said surface with a contour defined by said relative positions of said getters.

17. A layer of material as recited in claim 16, wherein said defect creating substance selected from the group consisting essentially of B, Ga, He, Ne, Ar, Kr, Xe, C, N, Be, and Group III materials.

18. A layer of material for use in connection with microcircuits or nanocircuits, said layer being expunged from a single crystalline semiconductor material, wherein said layer has a surface with a non-planar contour defined by the relative positions of a plurality of getters in said base material from which said layer is formed, wherein said layer is thereby adapted for use in connection with microcircuits, and wherein said layer is formed by the method comprising:
(a) introducing a defect creating substance into said base material wherein said substance functions as getters during subsequent processing of said base material;
(b) introducing a plurality of atoms into said semiconductor material at a location spaced apart from the location of said getters;
(c) transporting said atoms toward said getters; and
(d) expunging said layer from said base material in the region of said acceptor centers, whereby said expunged layer has said surface with a contour defined by said getters.

19. A layer of material as recited in claim 18, wherein said defect creating substance is selected from the group consisting essentially of B, Ga, He, Ne, Ar, Kr, Xe, C, N, Be, and Group III materials.

20. A layer of material for use in connection with microcircuits or nanocircuits, said layer being expunged from a single crystalline semiconductor base material, wherein said layer has a surface with a non-planar contour defined by the relative positions of a plurality of getters in said base material from which said layer is formed, wherein said layer is thereby adapted for use in connection with microcircuits or nanocircuits, and wherein said layer is formed by the method comprising:
(a) introducing a defect creating substance into said base material wherein said substance functions as getters during subsequent processing of said base material;
(b) introducing a plurality of atoms into said silicon material at a location spaced apart from the location of said getters;
(c) transporting said atoms toward said getters; and
(d) expunging said layer from said base material in the region of said getters, whereby said expunged layer has said surface with a contour defined by said getters.

21. A layer of material as recited in claim 20, wherein said defect creating substance is selected from the group consisting essentially of B, Ga, He, Ne, Ar, Kr, Xe, C, N, Be, and Group III materials.

22. A single crystalline semiconductor base material for use in connection with fabrication of microcircuits or nanocircuits, wherein said base material includes a non-planar contour line along which a layer can be expunged, said contour line defined by the relative positions of a plurality of getters in said base material, wherein said getters are formed by introducing a defect creating substance into said base material.

23. A material as recited in claim 22, wherein said defect creating substance is selected from the group consisting essentially of B, Ga, He, Ne, Ar, Kr, Xe, C, N, Be, and Group III materials.

24. A material as recited in claim 22, wherein said base material is processed according to the steps comprising:
(a) introducing a plurality of atoms into said material at a location spaced apart from the location of said getters; and
(b) transporting said atoms toward said getters.
